(19) United States
(12) Patent Application Publication
(10) Pub. No.: US 2010/0091470 A1
(43) Pub. Date: Apr. 15, 2010

(54) POWER TOOL WITH ELECTRONIC CONTROL UNIT

(76) Inventor: Carl Gunnar Östling, Nacka (SE)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 12/517,178

(22) PCT Filed: Nov. 28, 2007
(86) PCT No.: PCT/SE07/01049

§ 371 Date: Jun. 1, 2009

(30) Foreign Application Priority Data
Dec. 1, 2006 (SE) 0602574-6

(51) Int. Cl. H05K 7/00; B25B 23/147

(52) U.S. Cl. 361/752

(57) ABSTRACT

An electric power tool has a housing with an electric motor and an onboard electronic operation control unit. The control unit includes at least one printed circuit board carrying a number of electronic components and is supported by two rigid metal bars. The metal bars form high capacity motor current leads as well as heat transferring devices. A support casing of a non-conducting material forms together with the circuit boards and the metal bars a subassembly to be mounted in the tool housing.

The invention relates to an electric power tool including an electric motor and an onboard electronic motor operation control unit including electronic components.

In electric power tools of this type there is a difficulty to arrange conductors for conducting the high magnitude currents required to energize the motor of the tool. Such high magnitude currents are normally not possible to handle via the leads formed on circuit boards, because such leads could have small areas only and would cause very intense heat that would be detrimental to the electronic components carried on the circuit board. Instead, high magnitude current leads connecting the motor to a power source have normally been formed by a separate wiring which is space demanding and tricky to handle together with the circuit board or boards at the assembly of the tool.

Another problem concerned with this type of tools is the mechanical strength and durability of the circuit boards and, when applicable, also the connections between two or more circuit boards. Power tools are often exposed to accidental violent external forces during use which might cause damage to the circuit boards with loose shaken components etc. Also at assembly of the power tool there are situations where the sensitive circuit boards are exposed to damage risks.

Still another problem is to effectively duct away heat generated in certain electronic components and hence in certain areas of the circuit boards to avoid overheating of and damage to the components.

The main object of the invention is to provide an electric power tool with an onboard electronic operation control unit by which the above mentioned problems are avoided. This is obtained by providing high capacity motor current leads which also act as mechanical reinforcement means as well as heat ducting means for the circuit boards of the operation control unit.

Further characteristics and advantages of the invention will appear from the following specification and claims.

A preferred embodiment of the invention is below described in detail with reference to the accompanying drawing.

In the drawing

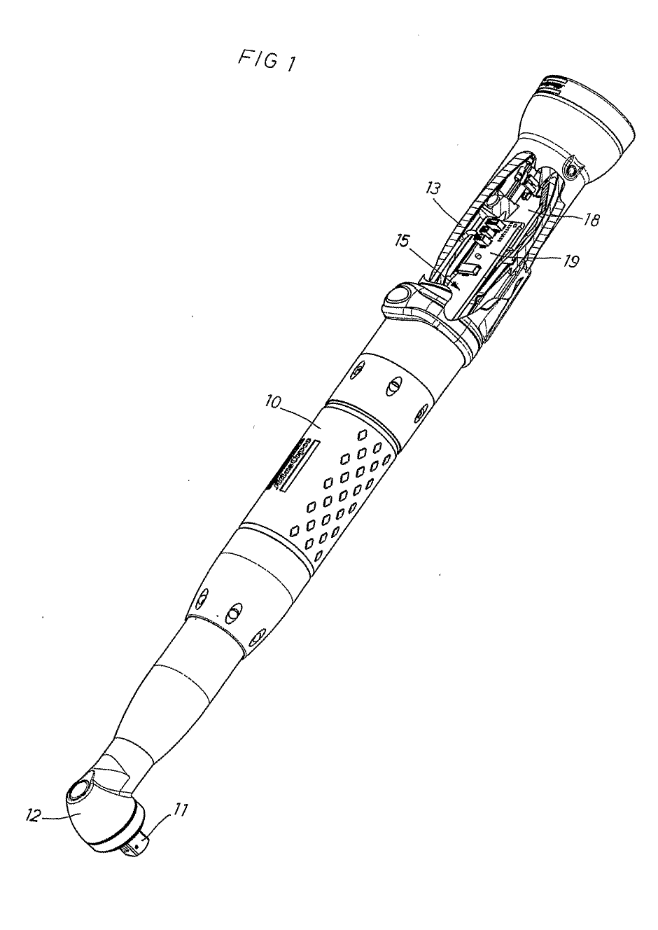

FIG. 1 shows a perspective view, partly in section, of an electric power tool according to the invention.

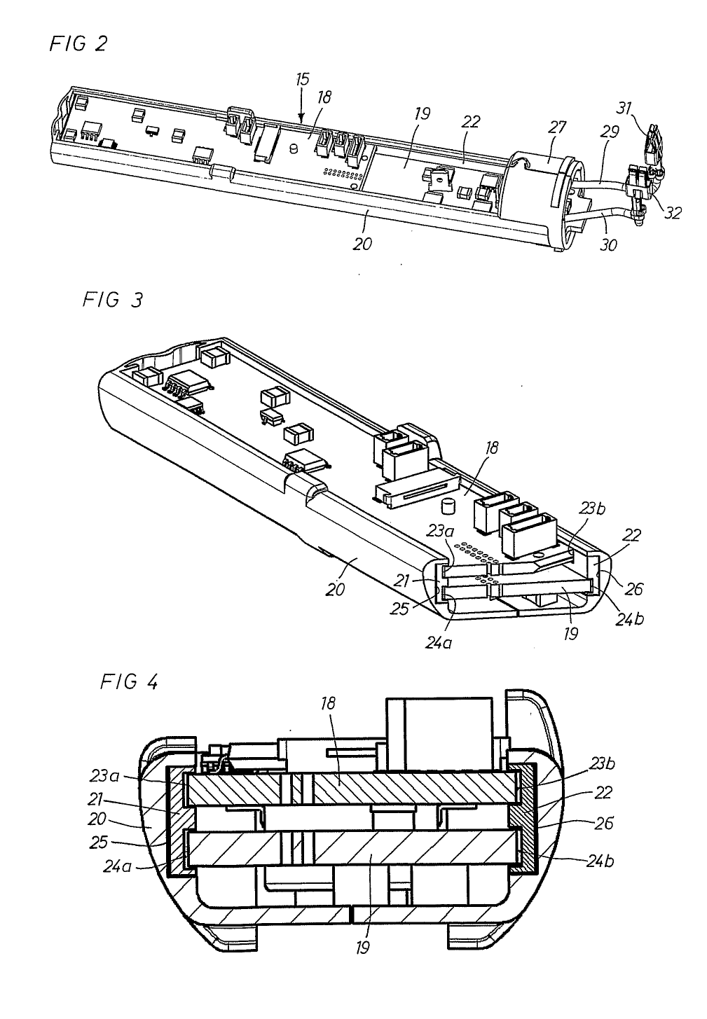

FIG. 2 shows a perspective view of the operation control unit included in the power tool in FIG. 1.

FIG. 3 shows a fractional perspective view, partly in section, of the circuit board arrangement of the operation control unit in FIG. 2.

FIG. 4 shows a cross section through the operation control unit.

The power tool illustrated in FIG. 1 is an electric angle nutrunner including a housing 10 with a non-illustrated electric motor connected to an output shaft 11 extending from an angle head 12 at the forward end of the housing 10. At its rear end the housing 10 is formed with a handle 13 for manual support of the tool. At the rear end of the handle 13 there is a non-illustrated connection means for connecting the tool via a cable to a stationary process control unit, and inside the handle 13 there is supported an electronic operation control unit 15. The latter is connected to the external connection means at the rear end of the handle as well as to the motor and to operation parameter responsive sensors, like for instance heat a sensor, that are usually supported in the housing 10.

The control unit 15 comprises two printed circuit boards 18,19 carrying electronic components connected to the motor and the sensors and arranged to supply motive power to the motor. As best illustrated in FIGS. 3 and 4, the printed circuit boards 18,19 are supported by two elongate rigid metal bars 21,22 extending along the sides of the circuit boards 18,19. These bars 21,22 are provided with grooves 23a,b and 24a,b, respectively, extending in the longitudinal direction of the bars 21,22 and in which the side edges of the circuit boards 18,19 are received, whereby the bars 21,22 serve as rigid reinforcement means for the circuit boards 18,19. The bars 21,22 are made of copper and are used as leads for the high magnitude motor currents, and due to the large area of these leads formed by the bars 21,22 the motor currents will not generate any heat. Instead, the copper bars 21,22 act as heat transferring means by ducting away heat generated by some of the electronic components in certain areas of on the circuit boards 18,19.

The entire control unit assembly, including the circuit boards 18,19 with the electronic components and the bars 21,22 are mounted in the tool housing 10 via a non-conductive casing 20. The latter is formed as an elongate tray with two parallel inner channels 25,26 on its side walls for receiving the bars 21,22. At its rear end the casing 20 is formed with a tubular portion 27 for proper orientation in the longitudinal direction of the tool housing 10. Preferably, the casing 20 is made of a suitable plastic material. From the rear end of the casing 20 there extend two sets of conductors 29,30 provided with connectors 31,32 for connection to the non-illustrated connection means at the rear end of the housing 10.

By designing the control unit 15 as a subassembly including the circuit boards 18,19, the motor current leading and circuit board reinforcing bars 21,22 and the casing 20 there is obtained a robust preassembled unit which is easy to merge with power tool housing 10 at the final assembly of the power tool without risking any damage to the separate parts of the control unit.

1. An electric power tool comprising:
a housing,
an electric motor, and
an onboard operation control unit comprising electronic components for motor power supply control, wherein the control unit comprises:
at least one printed circuit board carrying the electronic components, and
at least one rigid metal bar firmly attached to said at least one circuit board, and
wherein said at least one metal bar extends along at least a part of said at least one circuit board and is arranged to form a lead for the electric motor current and to reinforce physically said at least one circuit board.

2. A power tool according to claim 1, wherein said at least one metal bar is attached in intimate contact with said at least one circuit board so as to absorb and transfer heat from said at least one circuit board.

3. A power tool according to claim 1, wherein said at least one metal bar is provided with longitudinal grooves for receiving side edges of said at least one circuit board.

4. A power tool according to claim 1, wherein said at least one metal bar is received in an electrically non-conducting support casing in the housing (10), and wherein said support casing is arranged to form a support for said at least one circuit board and said at least one metal bar relative to the housing.

5. A power tool according to claim 1, wherein said at least one metal bar are two in number and extend substantially in parallel with each other.

6. A power tool according to claim 5, wherein said support casing has the form of an elongate tray with two parallel channels for receiving said metal bars.

7. A power tool according to claim 4, wherein said casing together with said at least one circuit board and said at least one metal bar form a subassembly for simple and safe assembly of the power tool.

8. A power tool according to claim 2, wherein said at least one metal bar is provided with longitudinal grooves for receiving side edges of said at least one circuit board.

9. A power tool according to claim 8, wherein said at least one metal bar is received in an electrically non-conducting support casing in the housing, and wherein said support casing is arranged to form a support for said at least one circuit board and said at least one metal bar relative to the housing.

10. A power tool according to claim 2, wherein said at least one metal bar is received in an electrically non-conducting support casing in the housing, and wherein said support casing is arranged to form a support for said at least one circuit board and said at least one metal bar relative to the housing.

11. A power tool according to claim 3, wherein said at least one metal bar is received in an electrically non-conducting support casing in the housing, and wherein said support casing is arranged to form a support for said at least one circuit board and said at least one metal bar relative to the housing.

12. A power tool according to claim 2, wherein said at least one metal bar are two in number and extend substantially in parallel with each other.

13. A power tool according to claim 3, wherein said at least one metal bar are two in number and extend substantially in parallel with each other.

14. A power tool according to claim 4, wherein said at least one metal bar are two in number and extend substantially in parallel with each other.

15. A power tool according to claim 8, wherein said at least one metal bar are two in number and extend substantially in parallel with each other.

16. A power tool according to claim 5, wherein said casing together with said at least one circuit board and said at least one metal bar form a subassembly for simple and safe assembly of the power tool.

17. A Power tool according to claim 6, wherein said casing together with said at least one circuit board and said at least one metal bar form a subassembly for simple and safe assembly of the power tool.
